(19) United States
(12) Patent Application Publication
(10) Pub. No.: US 2006/0011326 A1
(43) Pub. Date: Jan. 19, 2006

(54) Heat-exchanger device and cooling system

(76) Inventor: Yassour Yuval, Kibbutz Hasolelim (IL)

Correspondence Address: REED SMITH, LLP;ATTN: PATENT RECORDS DEPARTMENT, 599 LEXINGTON AVENUE, 29TH FLOOR, NEW YORK, NY, 10022-7650, US

(21) Appl. No.: 10/893,568

(22) Filed: Jul. 15, 2004

(51) Int. Cl. H05K 7/20

(52) U.S. Cl. 165/80.4; 165/168; 361/699

(57) ABSTRACT

A heat-exchanging device. The device comprises a block made from a heat-conducting material with a plurality of cooling tubes provided in it. Each of the cooling tubes has an inlet for receiving an inflow of a coolant fluid and an outlet for evacuating the coolant fluid, the inlet and the outlet of each cooling tubes are distributed on at least one active surface, which is substantially opposite a heat-transfer surface of the heat-exchanging device. Each cooling tube is designed to direct the coolant fluid towards and then away from said at least one heat-transfer surface. When subjected to a heat flux through the heat-transfer surface and when coolant fluid passes through the cooling tubes it absorbs heat from the block and evacuates it away.

### FIELD OF THE INVENTION

The present invention relates to cooling (or heating) systems. More particularly the present invention relates to a heat-exchanging device.

### BACKGROUND OF THE INVENTION

The continuing reduction in size of microelectronic components, such as chips, diodes, laser sources and other such devices, and the reduction in transistor rise time, presents a formidable challenge to the packaging industry. In order to facilitate effective near term utilization of the future microelectronic devices, the design and performance of first and second level packaging need a significant improvement with respect to the current state-of-the-art technology. Heat fluxes of various microelectronic devices exceeding 100 Watts per cm² are currently considered in the art.

Various solutions for cooling microelectronic devices have been suggested in the literature and are known in the art. The following are examples of air cooling systems.

In U.S. Pat. No. 4,447,842 (Berg) finned heat exchangers for electronic chips and cooling assembly were introduced. It features a pair of heat exchange fins mounted on the electronic chip, each projecting through a groove and into a channel of a cooling module, and kept in contact with a cooling surface of that module.

In U.S. Pat. No. 4,535,386 (Frey et. al.) a natural convection cooling system for electronic components was disclosed. The electronic components were to be mounted at the base of an enclosure, at an opening of an inner chimney, which separates the interior of the enclosure into forward and rearward compartments. The inner chimney serves to duct the heated air rising from the electronic components to the top of the enclosure. A heat exchanger is placed at the top of that enclosure, to cool the heated air, resulting in a cooler air movement downwardly, and thus establishing natural air turbulence within the enclosure.

Another cooling system was introduced in U.S. Pat. No. 4,158,875 (Tajima et. al.). In this invention the air cooling of the electronic components is achieved by a double-walled duct construction whereby air, as a coolant, is introduced, in a direction at high angles to the length of the heat generating electronic components.

In U.S. Pat. No. 4,837,663 (Zushi et. al.) a cooling system for an electronic apparatus was disclosed. It included a plurality of motherboards, each having a circuit board to be cooled, a blower for causing airflow, and a duct for directing the airflow between the motherboards.

To-date cooling systems are not efficient enough when higher rates of heat dissipation from electronic components are considered, and as technology proceeded to introduce micro electronic devices with higher performance parameters, with subsequently higher heat dissipation, there is a need for more efficient cooling systems.

It is a purpose of the present invention to provide a novel heat-exchanging device for cooling high-power devices.

Another purpose of the present invention is to provide such heat-exchanging device of high efficiency, both for cooling and heating missions.

Yet another purpose of the present invention is to provide such heat-exchanging device of high efficiency for cooling and heating missions where the device is designed to exchange heat by placing it in contact with a high-power device or by submerging its heat-transfer surface to a fluidic medium (liquid or gas).

Another purpose of the present invention is to provide such heat-exchanging device of high efficiency where gases such as air or liquids such as water are used as a coolant fluid.

### SUMMARY OF THE INVENTION

There is thus provided, in accordance with some preferred embodiments of the present invention, a heat-exchanging device comprising:
a block made from a heat-conducting material with a plurality of cooling tubes provided in it, each of the cooling tubes having an inlet for receiving an inflow of a coolant fluid and an outlet for evacuating the coolant fluid, the inlet and the outlet of each cooling tubes are distributed on at least one active surface, which is substantially opposite a heat-transfer surface of the heat-exchanging device, wherein each cooling tube is designed to direct the coolant fluid towards and then away from said at least one heat-transfer surface,
whereby when subjected to a heat flux through the heat-transfer surface and when coolant fluid passes through the cooling tubes it absorbs heat from the block and evacuates it away.

Furthermore, in accordance with some preferred embodiments of the present invention, the heat-conducting material is selected from the group of materials containing Aluminum and Copper.

Furthermore, in accordance with some preferred embodiments of the present invention, the device is provided with a heat-spreader coupled to the heat-transfer surface of the heat-exchanging device.

Furthermore, in accordance with some preferred embodiments of the present invention, the active surface is flat.

Furthermore, in accordance with some preferred embodiments of the present invention, the active surface is staggered.

Furthermore, in accordance with some preferred embodiments of the present invention, the active surface has levels of different elevations.

Furthermore, in accordance with some preferred embodiments of the present invention, the heat-transfer surface is flat.

Furthermore, in accordance with some preferred embodiments of the present invention, the cooling tubes are each U-shaped.

Furthermore, in accordance with some preferred embodiments of the present invention, the cooling tubes are each J-shaped.

Furthermore, in accordance with some preferred embodiments of the present invention, the cooling tubes are each V-shaped.

Furthermore, in accordance with some preferred embodiments of the present invention, the cooling tubes each have a diameter that is not greater than 1 mm.

Furthermore, in accordance with some preferred embodiments of the present invention, the cooling tubes each have a diameter that is not greater than 0.7 mm.

Furthermore, in accordance with some preferred embodiments of the present invention, the cooling tubes each have a height that is not greater than 10 mm.

Furthermore, in accordance with some preferred embodiments of the present invention, the cooling tubes each have a height that is not greater than 6 mm.

Furthermore, in accordance with some preferred embodiments of the present invention, the inlets and outlets of the cooling tubes are distributed on the active surface at a density of between 50 to 1000 pairs of inlets and outlets per cm square.

Furthermore, in accordance with some preferred embodiments of the present invention, the inlets and outlets cooling tubes are distributed on the active surface at a rate of between 100 to 600 pairs of inlets and outlets per cm square.

Furthermore, in accordance with some preferred embodiments of the present invention, the total area taken by the inlets and outlets of the cooling tubes amounts between 50 to 85 percent of the total area of the active surface.

Furthermore, in accordance with some preferred embodiments of the present invention, the fluidic coolant is gas.

Furthermore, in accordance with some preferred embodiments of the present invention, the fluidic coolant is air.

Furthermore, in accordance with some preferred embodiments of the present invention, the fluidic coolant is liquid.

Furthermore, in accordance with some preferred embodiments of the present invention, the fluidic coolant is water.

Furthermore, in accordance with some preferred embodiments of the present invention, the fluidic coolant is a mixture of fluids.

Furthermore, in accordance with some preferred embodiments of the present invention, the fluidic coolant is a two-phase fluid.

Furthermore, in accordance with some preferred embodiments of the present invention, the block is made from two parts, a first part comprising a plurality of ducts passing through the part and a second part comprising a plurality of basins, whereby the parts are joined thus fluidically connecting couples of ducts via a basin to define the cooling tubes.

Furthermore, in accordance with some preferred embodiments of the present invention, the block is made from a plurality of substantially parallel plates in which sections of the cooling tubes are carved out.

Furthermore, in accordance with some preferred embodiments of the present invention, sections of a delivery manifold are also carved out in the substantially parallel plates.

Furthermore, in accordance with some preferred embodiments of the present invention, sections of an evacuation manifold are also carved out in the substantially parallel plates.

Furthermore, in accordance with some preferred embodiments of the present invention, inlets and outlets of the cooling tubes are arranged in respective rows.

Furthermore, in accordance with some preferred embodiments of the present invention, inlets and outlets of the cooling tubes are arranged in adjacent twin-rows.

Furthermore, in accordance with some preferred embodiments of the present invention, inlets and outlets are arranged in a staggered formation.

Furthermore, in accordance with some preferred embodiments of the present invention, the rows are arranged in zones of varying row orientations.

Furthermore, in accordance with some preferred embodiments of the present invention, the device further comprises an evacuation manifold communicating with the outlets for evacuating the fluidic coolant.

Furthermore, in accordance with some preferred embodiments of the present invention, the evacuation manifold further comprises fine channels, each channel communicating with at least a portion of one row of outlets.

Furthermore, in accordance with some preferred embodiments of the present invention, the fine channels cross sectional area is larger at the entrance to the channels and smaller at the end of the channels.

Furthermore, in accordance with some preferred embodiments of the present invention, the device further comprises a delivery manifold communicating with the inlets for delivering the fluidic coolant.

Furthermore, in accordance with some preferred embodiments of the present invention, the delivery manifold further comprises fine channels, each channel communicating with at least a portion of one row of inlets.

Furthermore, in accordance with some preferred embodiments of the present invention, the fine channels cross sectional area is larger at the entrance to the channels and smaller at the end of the channels.

Furthermore, in accordance with some preferred embodiments of the present invention, each of the fine channels of the delivery manifold communicating with at least a portion of two adjacent rows of inlets.

Furthermore, in accordance with some preferred embodiments of the present invention, each of the fine channels of the evacuation manifold communicating with at least a portion of two adjacent rows of outlets.

Furthermore, in accordance with some preferred embodiments of the present invention, the delivery manifold is integrated at least partly above the active surface.

Furthermore, in accordance with some preferred embodiments of the present invention, the fine channels of the delivery manifold are integral channels provided at the active surface and penetrate the block.

Furthermore, in accordance with some preferred embodiments of the present invention, the delivery manifold and the evacuation manifold are integrated to the active surface of the block one above the other.

Furthermore, in accordance with some preferred embodiments of the present invention, the delivery manifold and the evacuation manifold are integrated in one layer at least partly above the active surface of the block.

Furthermore, in accordance with some preferred embodiments of the present invention, the fine channels of at least of the delivery manifold or the evacuation channels are integral channels provided at the active surface and penetrate to the block.

Furthermore, in accordance with some preferred embodiments of the present invention, the delivery manifold is designed to introduce the fluidic coolant from a first direction and the evacuation manifold is designed to evacuate the fluidic coolant from a second direction.

Furthermore, in accordance with some preferred embodiments of the present invention, the second direction is substantially opposite to the first direction.

Furthermore, in accordance with some preferred embodiments of the present invention, the delivery manifold is designed to introduce the fluidic coolant from two or more directions relative to the device.

Furthermore, in accordance with some preferred embodiments of the present invention, the inlets and outlets are distributed on the active surface at a varying density.

Furthermore, in accordance with some preferred embodiments of the present invention, the cross-section of the cooling tubes is substantially round.

Furthermore, in accordance with some preferred embodiments of the present invention, the cross-section of the cooling tubes is substantially rectangular.

Furthermore, in accordance with some preferred embodiments of the present invention, the cooling tubes have varying cross-sectional area.

Furthermore, in accordance with some preferred embodiments of the present invention, there is provided a heat-exchanging device for exchanging heat with a fluidic medium comprising:
a plate with a plurality of cooling tubes made from a heat-conducting material and extending from the plate, the cooling tubes aimed at being submerged in the fluidic medium, each of the cooling tubes having an inlet for receiving an inflow of a coolant fluid and an outlet for evacuating the coolant fluid, the inlet and the outlet of each cooling tubes are distributed on at least one active surface on the plate, wherein each cooling tube is designed to direct the coolant fluid towards and then away from the fluidic medium,
whereby when subjected to a heat flux through the heat-transfer surface and when coolant fluid passes through the cooling tubes it absorbs heat from the fluidic medium and evacuates it away.

Furthermore, in accordance with some preferred embodiments of the present invention, there is provided a cooling system for cooling a plurality of heat-dissipating electronic devices of an electronic system, the cooling system comprising:
a plurality of heat-exchangers, each heat-exchanger designed to be coupled to one heat-dissipating electronic device and comprising at least one block made from a heat-conducting material with a plurality of cooling tubes provided in it, each of the cooling tubes having an inlet for receiving an inflow of a coolant fluid and an outlet for evacuating the coolant fluid, the inlet and the outlet of each cooling tubes are distributed on at least one active surface, which is substantially opposite a heat-transfer surface of the heat-exchanging device, wherein each cooling tube is designed to direct the coolant fluid in the general direction of said at least one heat-transfer surface and then divert it away from said at least one heat-transfer surface, and fluidic coolant supply, for supplying fluidic coolant via piping to the plurality of heat-exchangers,
whereby when subjected to a heat flux through the heat-transfer surface and when coolant fluid passes through the cooling tubes of each heat-exchanger it absorbs heat and evacuates it away.

Furthermore, in accordance with some preferred embodiments of the present invention, the fluidic coolant is air.

Furthermore, in accordance with some preferred embodiments of the present invention, the fluidic coolant supply comprises an air blower.

Furthermore, in accordance with some preferred embodiments of the present invention, the fluidic coolant supply comprises a pressure pump.

Furthermore, in accordance with some preferred embodiments of the present invention, the fluidic coolant supply comprises a vacuum pump.

Furthermore, in accordance with some preferred embodiments of the present invention, the fluidic coolant supply comprises a compressor.

Furthermore, in accordance with some preferred embodiments of the present invention, the blower is also used for ambient cooling of the electronic system interior.

Furthermore, in accordance with some preferred embodiments of the present invention, the system further comprises a fan for ambient cooling of the electronic system interior.

Furthermore, in accordance with some preferred embodiments of the present invention, the system is further provided with pre-cooling means for pre-cooling the coolant fluid prior to passing it through the heat-exchangers.

Furthermore, in accordance with some preferred embodiments of the present invention, the system is further provided with evacuation means for evacuating hot fluidic coolant from the heat-exchangers.

Furthermore, in accordance with some preferred embodiments of the present invention, the evacuation means evacuates the hot fluidic coolant via piping to an external environment.

Furthermore, in accordance with some preferred embodiments of the present invention, the delivery pipe lines are insulated.

Furthermore, in accordance with some preferred embodiments of the present invention, the evacuation pipe lines are insulated.

Furthermore, in accordance with some preferred embodiments of the present invention, the electronic system comprises a plurality of electronic boards on which a plurality of heat-dissipating devices are mounted.

Furthermore, in accordance with some preferred embodiments of the present invention, at least one of the heat-exchangers cools an off-board element.

Furthermore, in accordance with some preferred embodiments of the present invention, the system, is further provided with a central thermal control for thermal management of the electronic system.

Furthermore, in accordance with some preferred embodiments of the present invention, there is provided a heat-exchanging device comprising:
a plurality of substantially parallel cooling fins provided between a first heat-spreader plate made from a heat-conductive material and a second substantially opposite cover plate, thus defining flow channels between the fins, each fin made from a heat conductive material and provided with a plurality of conduits passing through the fin, wherein the flow channels intermittently serve as supply and evacuation channels for a fluidic coolant, so that the coolant may pass through the conduits of fins,
whereby when subjected to a heat flux through the heat-transfer surface and when coolant fluid passes through the conduits it absorbs heat and evacuates it away.

Furthermore, in accordance with some preferred embodiments of the present invention, the supply channels are connected to a supply manifold.

Furthermore, in accordance with some preferred embodiments of the present invention, the evacuation channels are connected to an evacuation manifold.

Finally, in accordance with some preferred embodiments of the present invention, the cover plate is perforated to allow evacuation of hot fluidic coolant.

### BRIEF DESCRIPTION OF THE DRAWINGS

In order to better understand the present invention, and appreciate its practical applications, the following Figures are provided and referenced hereafter. It should be noted that the Figures are given as examples only and in no way limit the scope of the invention. Like components are denoted by like reference numerals.

FIG. 1a illustrates the basic cell of the heat-exchanger device having two internal U-tubes in accordance with a preferred embodiment of the present invention.

FIG. 1b illustrates a top view of the basic cell of FIG. 1a.

FIG. 1c illustrates a cross-sectional view of the basic cell of FIG. 1a.

FIGS. 1d-f illustrate U-tubes of rectangular cross-section and an exemplary way of implementation.

FIG. 2a illustrates the basic cell of the heat-exchanger device having two external U-tubes in accordance with another preferred embodiment of the present invention.

FIG. 2b illustrates a top view of the basic cell of FIG. 2a.

FIG. 2c illustrates a cross-sectional view of the basic cell of FIG. 2a.

FIGS. 3a-d illustrate the rule of multiplying the number of U-tubes within a heat-exchanger device, whilst at the same time reducing their dimensions.

FIG. 4a illustrates a schematic top view of a heat-exchanging device having feeding and evacuation coolant channeling in accordance with another preferred embodiment of the present invention.

FIG. 4b illustrates a schematic top view of the coolant feeding and evacuation arrangement shown in FIG. 4a.

FIGS. 4c-e illustrate some optional structures of fine delivery and evacuation channels.

FIG. 5a is a cross-sectional view of a local coolant feeding and evacuation channels for a heat-exchanging device in accordance with another preferred embodiment of the present invention.

FIG. 5b illustrates a schematic 3D of the coolant delivery channeling shown in FIG. 4a (up-side down).

FIG. 6a depicts a heat-exchanging device in accordance with a preferred embodiment of the present invention mounted over an electronic component (such as CPU) having similar dimensions having a structure of four layers.

FIG. 6b depicts a heat-exchanging device in accordance with a preferred embodiment of the present invention mounted over an electronic component (such as CPU) having similar dimensions having a structure of three layers.

FIG. 6c illustrates a 4-layers heat-exchanging device in accordance with another preferred embodiment of the present invention mounted over an electronic component (such as CPU) having smaller dimensions with respect to the heat-exchanging device.

FIGS. 6d-e illustrate optional setups of the heat-exchanging device on top of the heat-generating element, in accordance with a preferred embodiment of the present invention.

FIGS. 6f-h illustrate optional shapes of U-tubes design with respect to the active surface of a heat-exchanging device, in accordance with a preferred embodiment of the present invention.

FIG. 7a illustrates typical arrangement of U-tubes of a heat-exchanging device, in accordance with a preferred embodiment of the present invention.

FIG. 7b illustrates a proposed coolant delivery and evacuation ducting for a heat-exchanging device of FIG. 7a, in accordance with a preferred embodiment of the present invention.

FIG. 8a illustrates a multi-zonal arrangement of U-tubes of a heat-exchanging device, in accordance with another preferred embodiment of the present invention.

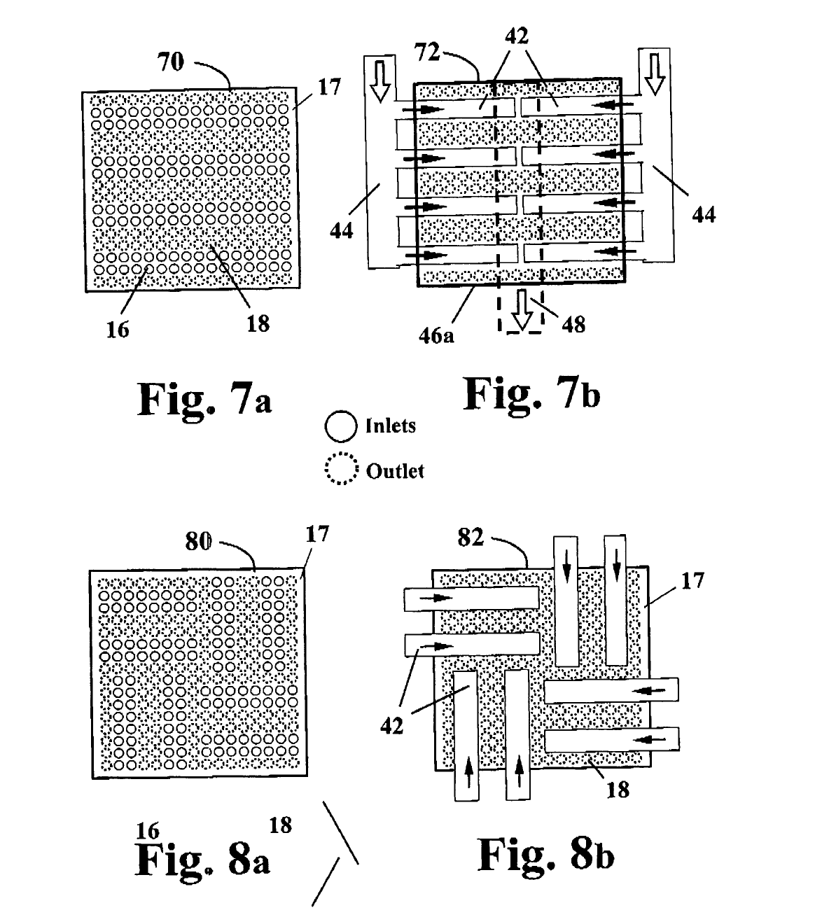

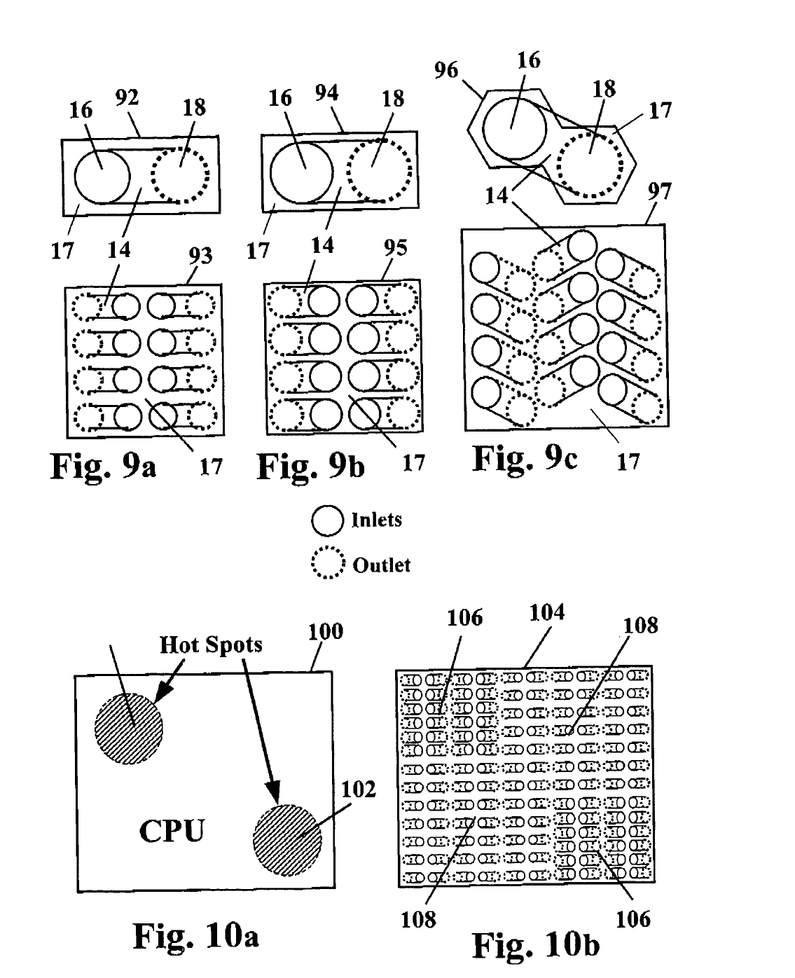

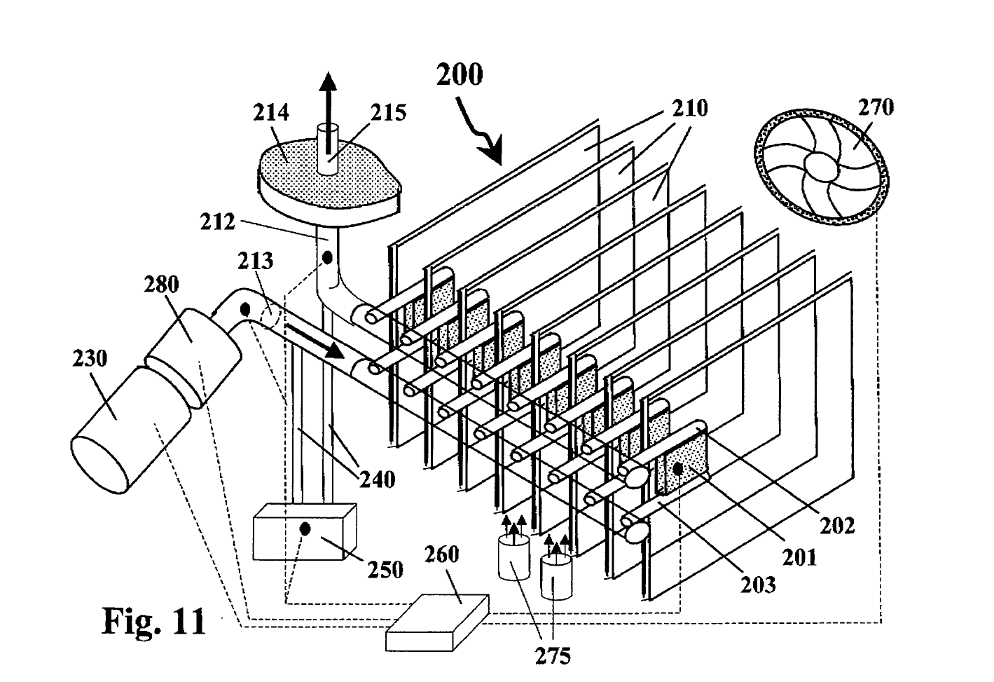

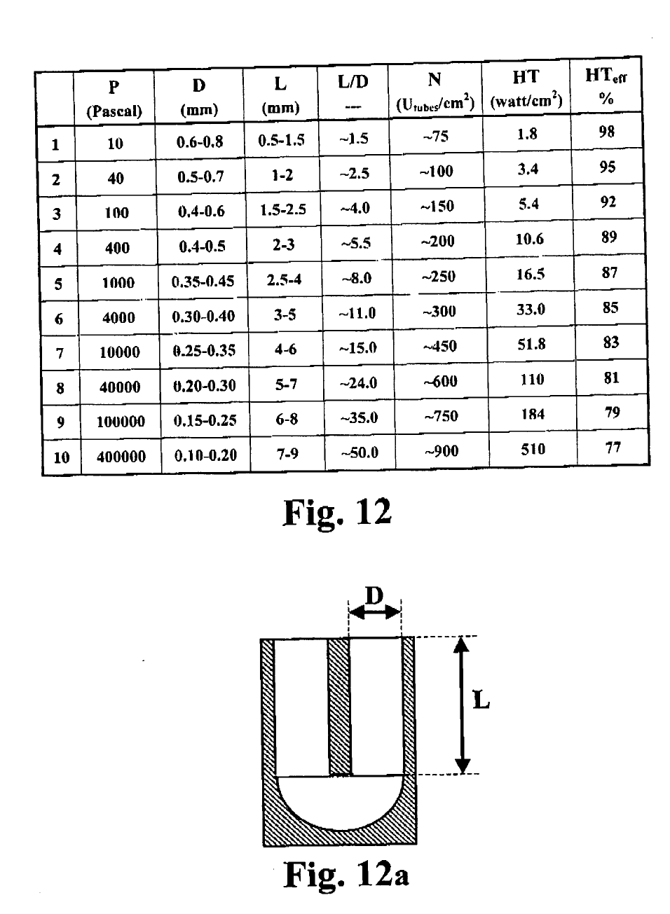

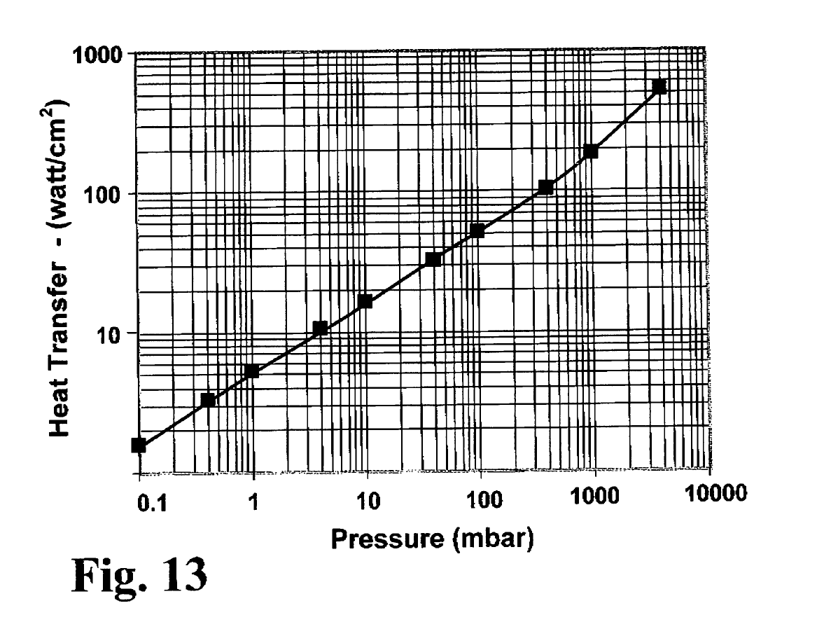

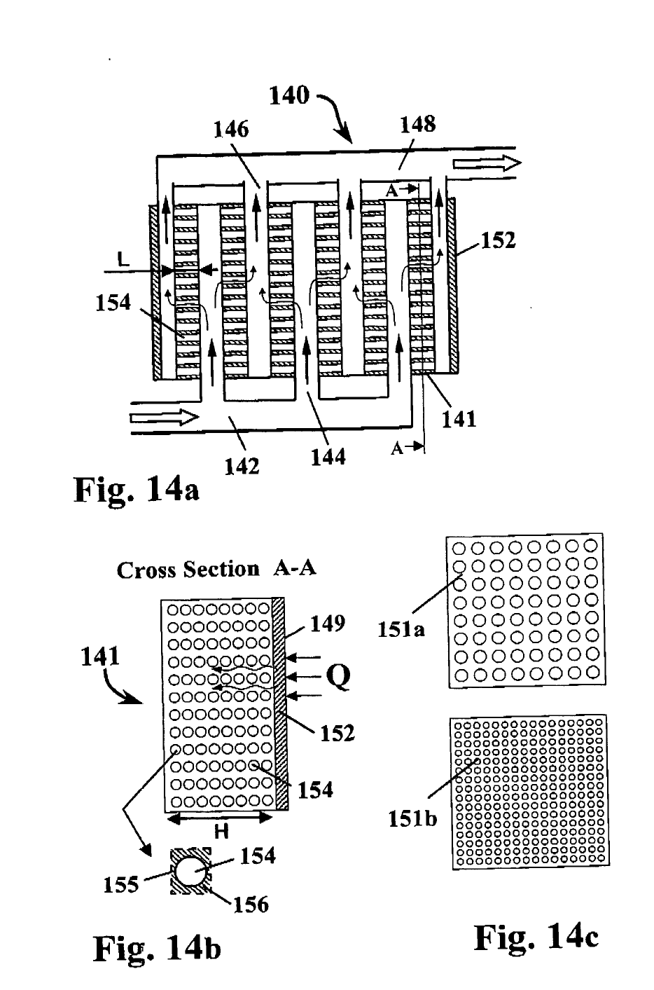

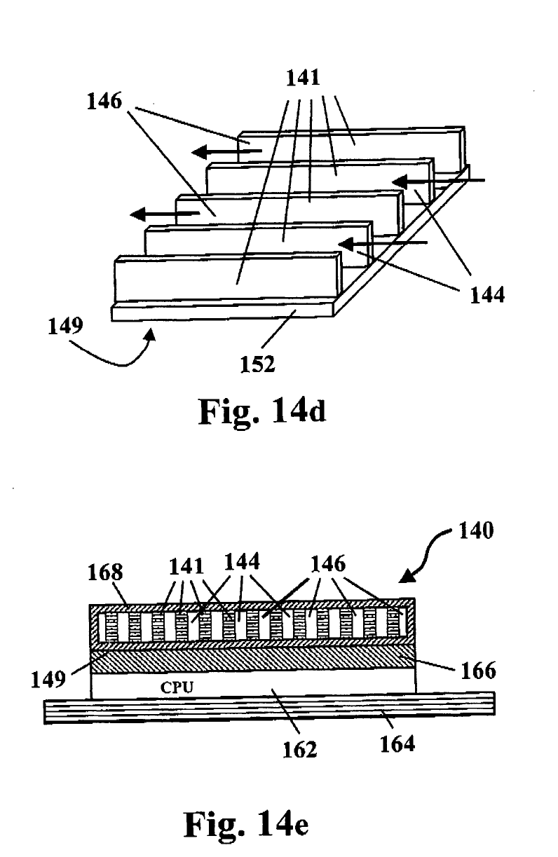

FIG. 7b illustrates a proposed coolant feeding and evacuation ducting for a heat-exchanging device of FIG. 8a, in accordance with a preferred embodiment of the present invention.

FIG. 9a-c illustrates various U-tube's basic cell arrangements in accordance with some preferred embodiment of the present invention.

FIG. 10a illustrates an electronic component with localized hot spots, typically hotter than other zones on that component.

FIG. 10b illustrates a proposed U-tubes arrangement of a heat-exchanging device, with corresponding varying density (with respect to the component of FIG. 10a).

FIG. 11 illustrates a cooling system for servers based on a plurality of U-tubes heat-exchanging devices, in accordance with a preferred embodiment of the present invention.

FIG. 12 is a table showing optimized data resulted from virtual prototyping simulation of a heat-exchanger device having optimized U-tubes for different supply pressure.

FIG. 12a defines the parameters L and D associated with the table shown in FIG. 12.

FIG. 13 is a graph showing the calculated optimized heat removal of the heat-exchanger device having optimized U-tubes for different supply pressure.

FIG. 14a illustrates a heat-exchanger device in accordance having through-tubes (I-tubes) with yet another preferred embodiment of the present invention.

FIG. 14b illustrates a single cooling fin of the heat-exchanger device shown in FIG. 14a (cross-section A-A in FIG. 11a).

FIG. 14c illustrates I-tubes arrangements with fine and coarse density for the cooling fins of the heat-exchanger device shown in FIG. 14a.

FIG. 14d illustrates a 3D view of the heat-exchanger device shown in FIG. 14a.

FIG. 14e illustrates a cross-sectional view of the heat-exchanger device shown in FIG. 14a, mounted over an heat-generating element (such as CPU).

### DETAILED DESCRIPTION OF PREFERRED EMBODIMENTS

The present invention typically relates to a heat-exchanging device, aimed in particular at cooling electronic components (such as PC CPUs and main-frames or server's CPUs, electro-optic component that waste heat at small area and other general purpose heat-dissipating electronic components). Hereafter we shell refer only to cooling missions although the heat exchanger of the present invention may be implemented for heating missions too.

In principle, a heat-exchanging device in accordance with some preferred embodiments of the present invention comprises a block having at least two surfaces. One surface is subjected to a heat flux (to be refer to as the HT (heat-transfer) surface), for example by attaching it to a heat dissipating element, and a substantially opposite active surface. The block constitutes the heat exchanger body, and is made of a heat-conducting material with a plurality of small cooling tubes provided in it, each of the cooling tubes having an inlet for an inflow of the coolant fluid and an outlet for evacuating the coolant fluid. The cooling tubes are distributed on the block surfaces or surfaces which are generally substantially opposite the heat-transfer surface (or surfaces)- to be refer as the active surface. The cooling tubes are oriented, at least at portions near the inlets and outlets, substantially normal to the active surfaces, so as to allow local heat-exchanging by the coolant fluid that is passed through each of the cooling tubes. A coolant fluid supplier, fluidically connected (optionally by an integral manifold) to the inlets of each of the cooling tubes, so as to drive the coolant fluid through the cooling tubes.

The heat-exchanging device of the present invention can also be a large device that may effectively be used for general-purpose industrial heat-exchange applications, for both heating and cooling. In the present specification we shell specifically refer to cooling, but heating applications are applicable too, as heat exchange deals with both.

A main aspect of the cooling device in accordance with the present invention is the implementation of various arrangements of heat-exchanging devices to meet specific heat-exchange requirements.

An important aspect of the heat-exchanging device in accordance with the present invention is the provision of a heat-exchanger comprising a body, made of heat-conducting materials known in the art (for example, Aluminum or Copper) incorporating a plurality of ducts, significantly increasing the overall external surfaces of the body.

Another main aspect of the present invention is the provision of a flow of coolant gas or fluid through the ducts for acquiring heat from the body and evacuating it away.

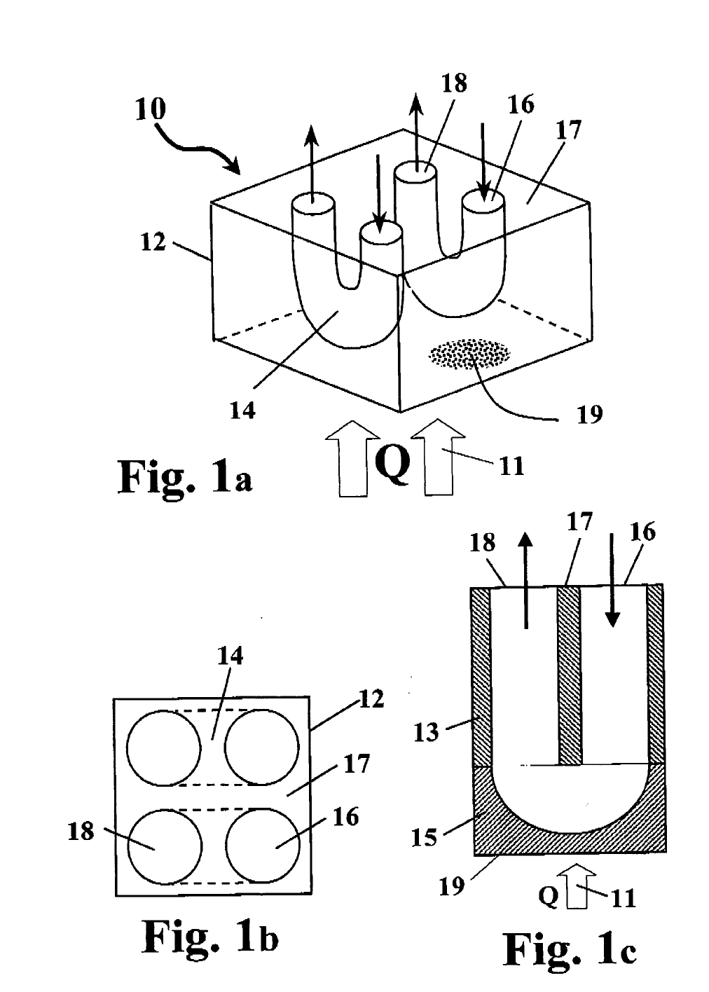

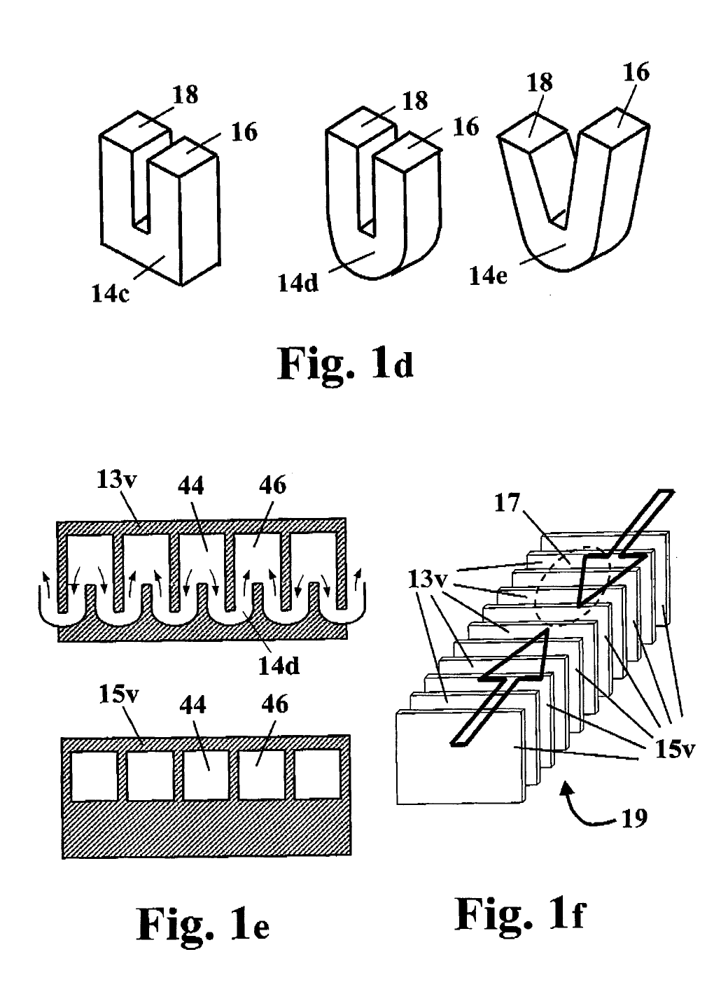

Reference is made to FIG. 1a illustrating a concept for a heat-exchanger device in accordance with a preferred embodiment of the present invention where internal U-tubes are implemented.

A basic cell of heat exchanging device 10 in accordance with a preferred embodiment of the present invention comprises a small portion of the main body 22 of the heat exchanger of the present invention (here depicted in the form of a rectangular block, but the shape may vary) made form a heat-conducting material with two U-tubes 14 provided in the body. Each duct has an inlet 16 and outlet 18. Both are located on the active surface 17 of 10. The heat flux 11 of the object to be cooled is coming from the HT-surface 19 which is the bottom surface of 12.

The twin U-tubes of the basic cell shown in FIG. 1a are U-shaped, but other general shapes are possible too. A heat-exchanging coolant fluid (for heating or cooling), which may be gas (for example, Air, Helium or Nitrogen but other coolant gases may be used too) or liquid (for example, Water, Oil, but other liquid coolants may be used too), is passed through the U-tubes and exchanges (absorbs or delivers) heat and is then evacuated away from the U-tubes.

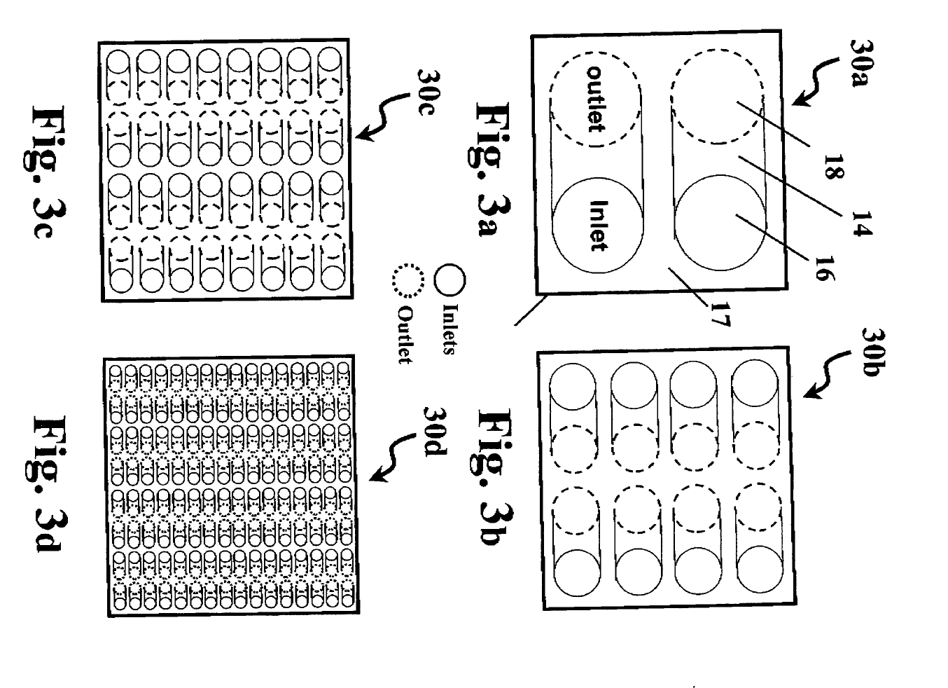

The coolant may also comprise a mixtures of fluids, single phase or twin-phase of fluids may be implemented, and it may also include phase changes to enhance heat-transfer. The overall internal surface of the plurality of U-tubes that is densely distributed over the heat-exchanging active surface 17 (see for example FIG. 3d) creates high potential of heat removal associated with the heat-exchanger of the present invention.

The heat exchanging takes place when the heat exchanger is adjacent to a heat-dissipating device (such as a CPU) and the heat-flux from that device, denoted by Q (11) passes into body 12, through the heat transfer (HT) surface 19. As the coolant is passed through the U-tubes, it absorbs the heat and evacuates it away.

FIG. 1b illustrates a top view of the basic cell 14 shown in FIG. 1a. FIG. 1c illustrates a cross-sectional view of the basic cell 14 shown in FIG. 1a. Note that for practical purposes, the U-shaped duct may be easily manufactured by producing a first block 13 perforated with ducts passing through it and a second block 15 of corresponding concave basins (dents), and coupling the two blocks together so that U-shaped ducts are formed within.

The cross-section area of the U-tubes and their shape may vary downstream. FIG. 1d illustrates in accordance with another preferred embodiment of the present invention a general view of U-tubes 14c and 14d that have rectangular shape, where U-tubes 14c (the connecting-channels between the inlet 16 and the outlet 18) have a more rounded shape. Both tube embodiments (14c and 14d) have a rectangular cross-section. Such U-tubes may be created for example by attaching a plurality of parallel plates as shown in FIG. 1f, oriented at a general direction that is perpendicular both to the active surface 17 and the HT-surface 19 where plates 13v encase in between them the U-tubes, fine delivery channels (44) and the fine evacuation channels (46), and intermediate dividing plates 15v encasing only the fine delivery channels (44) and the fine evacuation channels (46).

A three-dimensional version of U-tubes 14e is shown in FIG. 1d to indicate that the centerline of the U-tube (with respect to its cross section) may not belong to a plane.

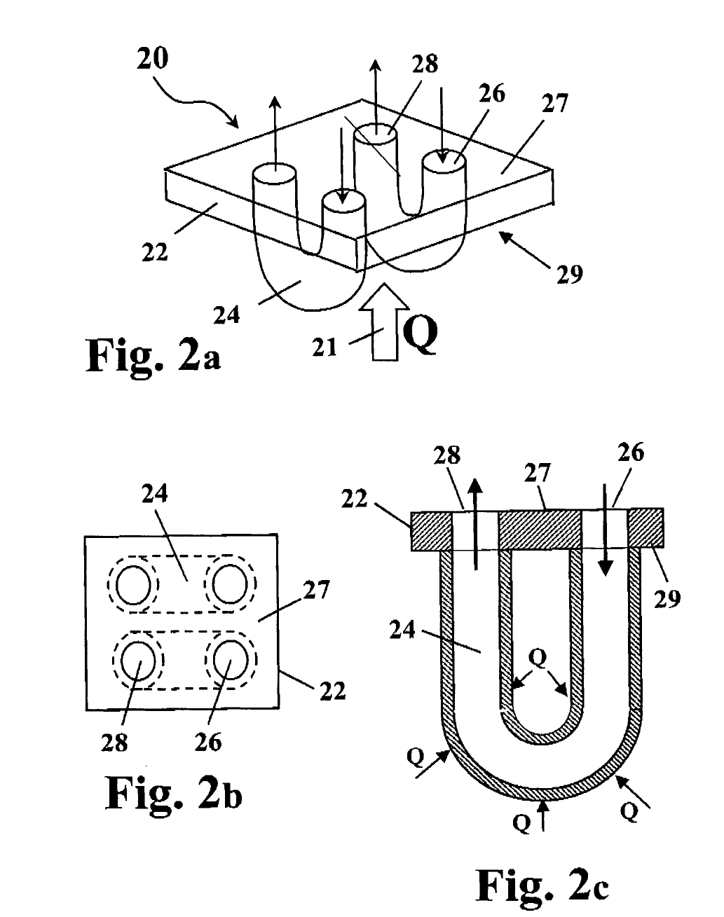

Reference is made to FIG. 2a illustrating a heat-exchanger device in accordance with another preferred embodiment of the present invention where external U-tubes are implemented. This version of the heat-exchanger of the present invention is capable of removing heat from a fluid as it is placed with its U-tubes submerged in that fluid.

A basic cell of heat exchanging device 20 in accordance with another preferred embodiment of the present invention comprises a small portion of the main body 22 of the heat exchanger of the (here depicted in the form of a rectangular box, but the shape may vary) preferably made form a heat-conducting material with two external U-tubes 24 provided in the body. Each U-tube has an inlet 16 and outlet 18, both located on the active surface 27 of 20. In this case the U-tubes 24 are exposed extending from the HT-surface 29 and the heat flux Q (21) is absorbed mostly through the outer surface of 24.

FIG. 2b illustrates a top view of the basic cell 24 shown in FIG. 2a. FIG. 1c illustrates a cross-sectional view of the basic cell 14 shown in FIG. 2a. One can see the advantage of the embodiment shown in FIG. 2a in dealing with heat-flux Q not only from the bottom, but also from the surrounding space. This embodiment would be recommended for use when the ambient atmosphere (or other gas or fluid) needs to be cooled or heated using the device of the present invention.

FIGS. 3a through 3d illustrate, with respect to a preferred embodiment of the present invention, a possible principle of increasing the number of U-tubes within a single heat-exchanger device, whilst at the same time the U-tubes dimensions are scaled down in such a way that the weight of the heat-exchanger device is kept relatively constant but the overall internal surface area of the plurality of U-tubes of the heat-exchanger device is substantially increased. In FIG. 3a the heat-exchanger device 30a comprises of one basic cell with two U-tubes similar to the one shown in FIG. 1. FIG. 3a shows more dense heat-exchanger device 30b having 8 U-tubes. In fact, device 30b includes 4 basic cells. Devices 30a and 30b are of similar sizes and thicknesses, but the U-tubes of 30b are smaller by factor of two whereas the number of U-tube is increased by a factor of four. Accordingly the internal surface area of the heat-exchanger device 30b is increased by factor of 2 with respect to 30a. Similarly, the heat-exchanger device 30c (FIG. 3c) has 64 U-tubes and the internal surface area of the heat-exchanger device 30c is increased by a factor of four with respect to 30a. The heat-exchanger device 30d (FIG. 3d) has 128 U-tubes and the internal surface area of the heat-exchanger device 30d is increased by a factor of 8 with respect to 30a.

For reasons of clarification, in FIGS. 3a-d a dashed line was used to draw the outlets of the U-tubes, and it was further applied when necessary in the following figures.

When going to more and more dense arrangements, very high number of smaller and smaller U-tubes may be provided in a heat-exchanger device of the present invention. Typically for CPU cooling (without derogating the generality), the U-tube inlet & outlet diameter is between 0.8 mm to 0.16 mm and accordingly as much as 50 to 1200 inlets and outlets are provided in one square centimeter (see also the table shown in FIG. 13).

It is evident that reducing the dimensions of the ducts to a miniaturized scale provides substantially greater internal surface for the heat-exchanging body. By “internal surface” is meant the entire surface of the body coming in contact with the coolant. Obviously, the greater that surface the more efficient the heat-transfer is to (or from) the coolant agent but also pressure losses may by considered with respect to the optimization of the heat-exchanger device of the present invention.

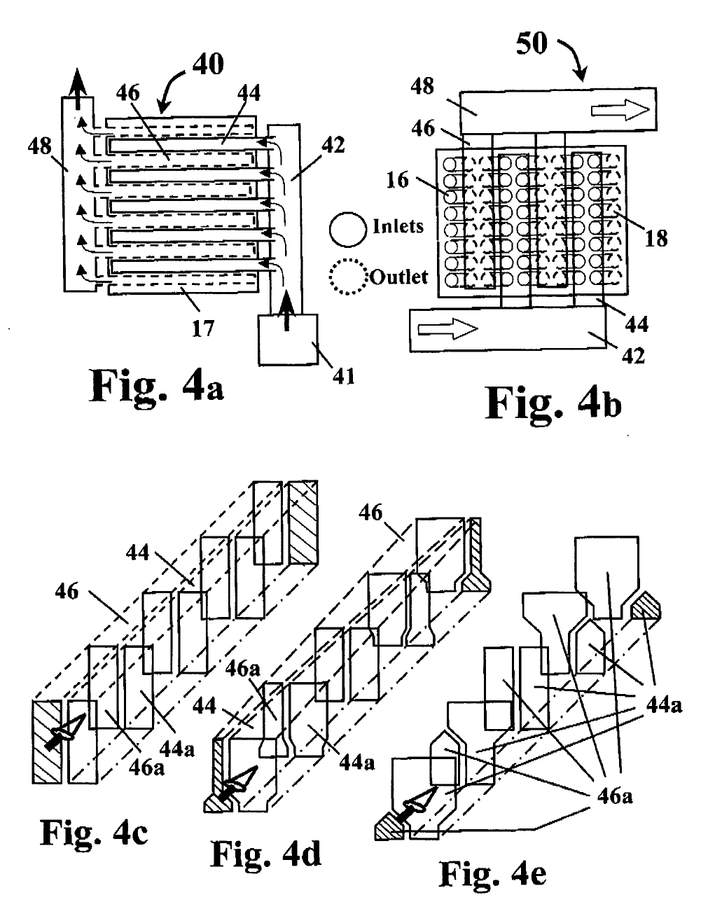

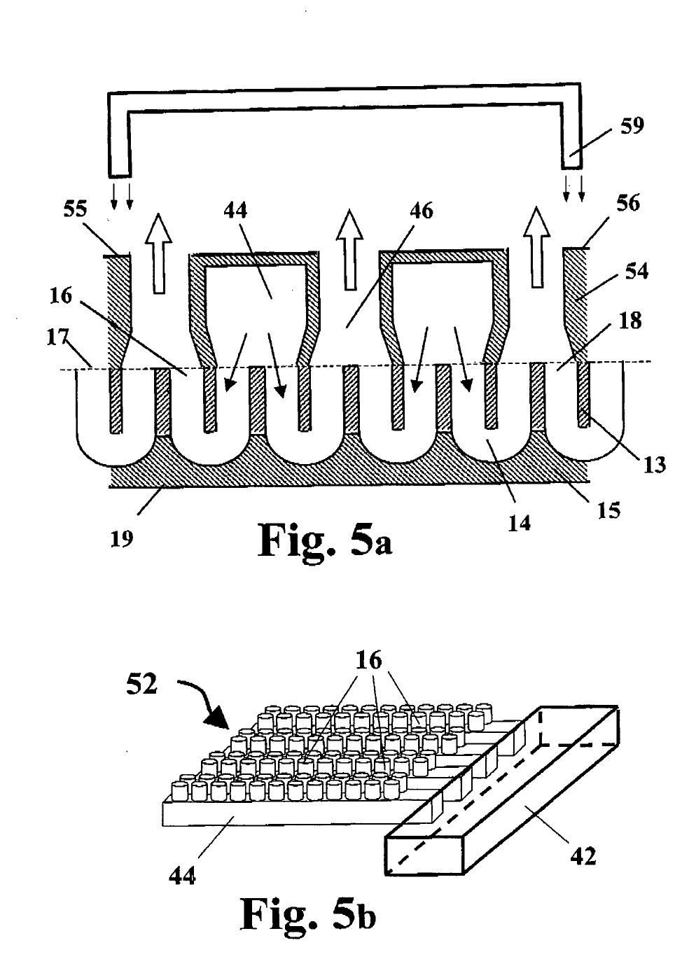

FIG. 4a illustrates a schematic top view of a heat-exchanging device in accordance with a preferred embodiment of the present invention. In this embodiment integral delivery and evacuation channeling of the coolant is presented. The heat exchanger 40 having a large number of U-tubes (see for example FIG. 5a) gets the coolant through a tree-like channeling where each of the u-tubes is fed by one of a plurality of fine integral channels 44 that are attached to the active surface 17 of 40. The fine delivery channels 44 are connected to the main delivery manifold 42 that is connected to an air (or other coolant) source such as fan, blower or pump that provides a predetermined mass flow rate at a predetermined pressure drop. Optionally, evacuation channeling may be applied, whereby a tree-like channeling where each of the u-tubes is connected to one of a plurality of fine integral channels 46 that attached to the active (top) surface 17 of 40 is used. The fine evacuation channels 46 are connected to the main evacuation manifold 48 that removes the already heated coolant away, preferably to the ambient atmosphere or further away (meaning that the heated coolant is not recycled and therefore has no heating effect on the device).

Alternatively, vacuum pump or any other suction device may be used to provide the pressure drop for driving the coolant through the heat exchanger of the present invention. In that case the evacuation channeling must be applied (for example when sucking and using the surrounding air as coolant) and adding delivery channels becomes an option only. It has to be emphasized that in some applications both blowers (or pumps) at the entrance to the delivery channels and vacuum means at the exit of the evacuation channels may be used.

FIG. 4b is another schematic top view of the delivery and evacuation channeling shown in FIG. 4a. The main delivery manifold 42 is fluidically connected to a plurality of fine delivery channels 44, and channels 44 are fluidically connected to each of the inlets 16 of the heat exchanger device 50. The main evacuation manifold 48 is fluidically connected to a plurality of fine evacuation channels 46, and channels 46 are fluidically connected to each of the outlets 16 of the heat exchanger device 50. In this arrangement, inlets 16 of two adjacent rows of U-tubes are juxtaposed, being fed through one delivery channel thus cutting to half the number of fine delivery channels, and the same is valid with respect to the evacuation channels. Notice that the evacuation and the fine delivery channels may both be applied in the same layer, thus presenting a structure of 3 layers.

The fine delivery channels 44 and 46 at FIG. 4b can be designed by applying uniform cross-section distribution as shown in FIG. 4c. However, in order to reduce pressure losses it is beneficial, with respect to a preferred embodiment of the present invention, to apply convergence cross-section distribution for the fine delivery channels and divergence cross-section distribution for the fine evacuation channels as shown in FIGS. 4d and 5e. In FIG. 4d the cross-sections 44a and 46a are distributed by changing the width of channels 44 and 46 while keeping the height constant and in FIG. 4e the cross-sections are distributed by changing both the width and the height of channels 44 and 46. The following comments are useful for better understanding of FIG. 4c-e

The divergence and convergence are related to the direction of the flow.

The area of each pair of cross sections (of 44a and 46a) at the cross-flow plane is constant and therefore it is a tradeoff matter of how to distribute the area between 44 and 46.

The cross sections shaded by diagonal lines are the solid end of the channels.

The elongated rectangular opening of all channels shown in FIG. 4c-e are similar (see also FIG. 4b). Notice that these channels are facing the active-surface of the heat exchanger device of the present invention and are fluidically connected to the inlets and the outlets of the cooling tubes.

FIG. 5a illustrates a cross-sectional view of the heat-exchanger device with respect to a preferred embodiment of the present invention including the delivery channeling and evacuation openings. This embodiment comprised of 3 attached blocks, the first block 13 of passing through ducts, a second block 15 of corresponding concave basins (both creating the plurality of U-tubes), and the third one is block 54 that includes a plurality of fine delivery channels 44 and openings 55 for evacuation. Here the fine delivery channels 44 are connected to the inlets 16 of U-tubes 14 and the heated coolant is evacuated from surface 56 of block 54. However, by adding another layer (59, not attached in the figure for reason of clarity, but in reality it is attached), evacuation channeling may be easily applied, thus creating a four-layer structure.

FIG. 5b illustrates 3 dimensional view of the delivery channeling of FIG. 4a. It is an up-side-down drawing that shows the plurality of inlets 16 of the U-tubes fluidically connected to the fine delivery channels 44 and the plurality of channels 44 that are fluidically connected to the main delivery manifold 42.

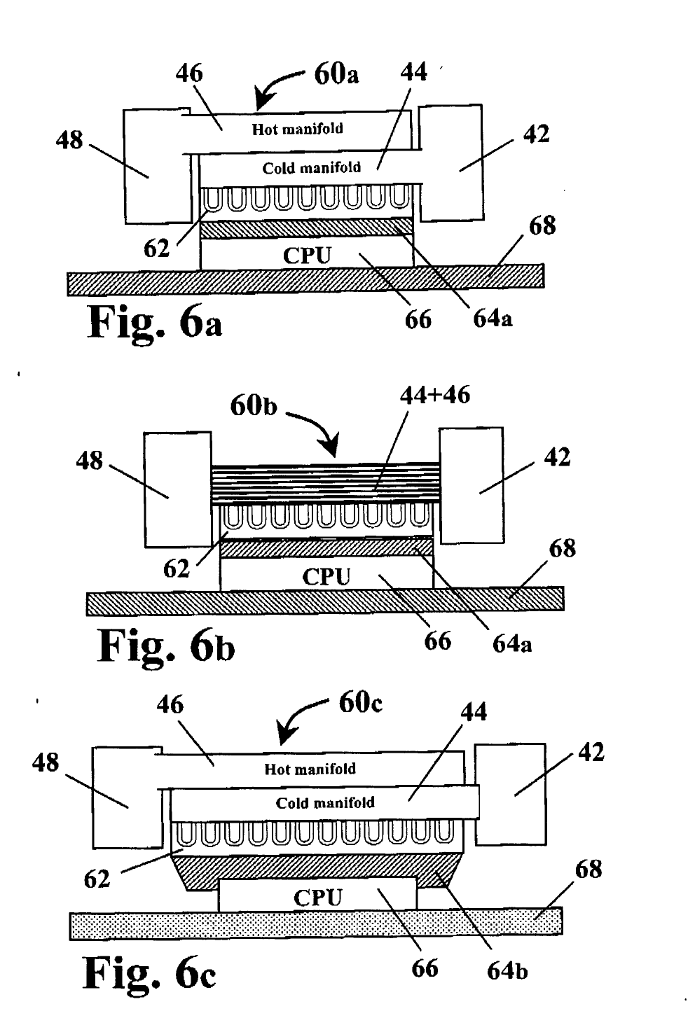

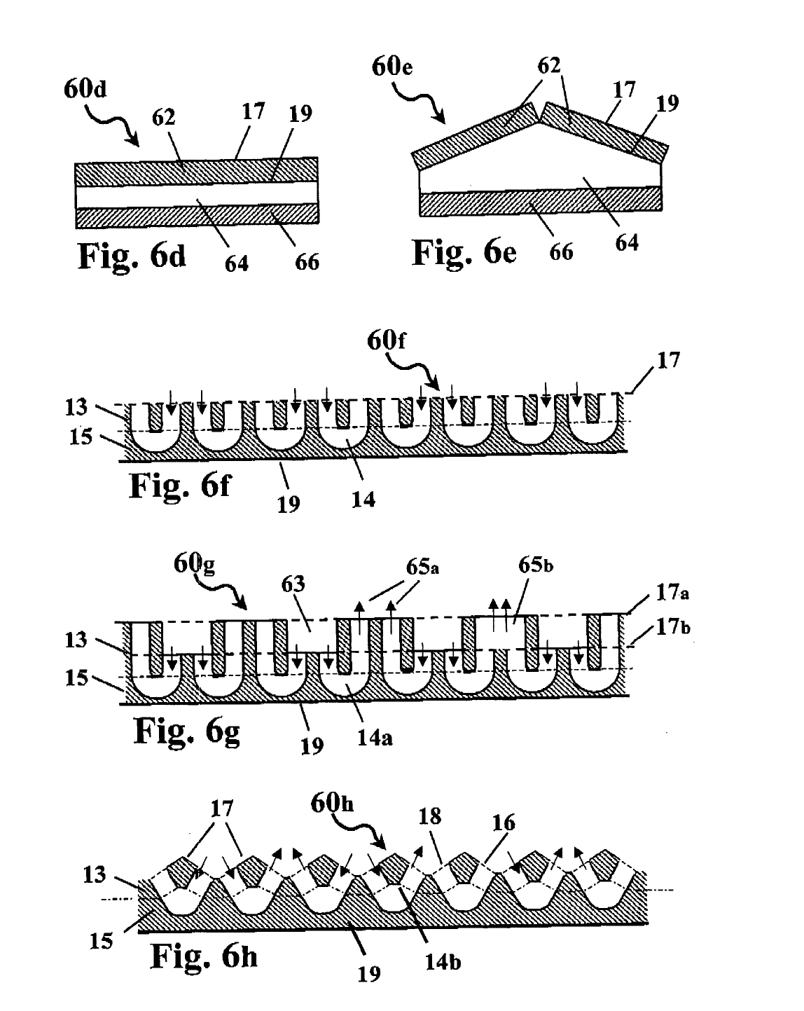

FIG. 6a depicts a heat-exchanging device 60a based on U-tubes in accordance with a preferred embodiment of the present invention, mounted over an electronic component 66 (CPU) on board 68 where a heat spreader 64a made of conductive material exists between 66 and 60a (U-tubes block 62 of 60a is in fact attached to 64a). This is a schematic drawing showing two levels of fine channels where the fresh air supply is delivered by the fine delivery channels block 44 that is attached to the U-tubes black 62 and fluidically connected to the inlets of each of the U-tubes. Hot air emerging from the U-tubes outlets is evacuated by the fine evacuation channels block 46 on top of 44. The main fresh air supply manifold 42 is fluidically connected to each of the fine delivery channels of 44, and the main evacuation manifold 48 is fluidically connected to each of the fine evacuation channels of 46, where channels 46 may exhaust the hot air to any desired space, preferably to a far environment.

FIG. 6b depicts a heat-exchanging device 60b based on U-tubes in accordance with another preferred embodiment of the present invention, mounted over an electronic component 66 (CPU) on board 68 where a heat spreader 64 is placed between 66 and 60b. Device 60b differs from device 60a of FIG. 6a only in using one layer of fine channels (44+46) as shown in FIG. 4a, thus reducing the overall width of 60b with respect to 60a.

FIG. 6c depicts a heat-exchanging device 60c based on U-tubes in accordance with another preferred embodiment of the present invention, mounted over an electronic component 66 (CPU) on board 68 where a heat spreader 64b placed between 66 and 60c. 60c has a similar stricture to device 60a of FIG. 6a but the heat spreader 64b has larger dimensions than 66. Accordingly the dimensions of 62 are enlarged also. Without derogating generality, a typical ratio between the top surface area of 66 and the effective area of 60c (i.e. the HT-surface 19 of FIG. 1) can be as much as 8:1 in case of CPU cooling.

FIG. 6d illustrates in accordance with a preferred embodiment of the present invention a planar setup 60d where a flat heat-exchanging device 62 is mounted over a flat electronic component 66 (for example, a CPU) and a flat heat-spreader 64 is placed in between them. This is a common setup where the HT-surface 19 and the active surface 17 of 62 are flat, but other alternatives of non-planner setups are possible too, as shown in FIG. 6e. FIG. 6e illustrates in accordance with another preferred embodiment of the present invention a non-planar setup 60e where two flat heat-exchanging devices 62 are mounted at an angle of inclination over a flat electronic component 66 (for example, a CPU) and a heat-spreader 64 in between them where 64 is flat from the “CPU side” and have two incline HT-surfaces 19 where 62 are mounted.

FIG. 6f illustrates, in accordance with a preferred embodiment of the present invention, a cross sectional view of a heat-exchanging device 60f, in accordance with another preferred embodiment of the present invention, built of two jointed blocks 13 & 15 (see FIG. 1). This cross sectional view includes a row of a plurality of U-tubes 14, where the both the inlets and the outlets of the U-tubes are located at the active-area 17 of 60f. However, FIG. 6g illustrates, in accordance with another preferred embodiment of the present invention, a cross sectional view of a heat-exchanging device 60g, built of two jointed blocks 13 & 15. This cross sectional view includes a row of a plurality of U-tubes 14a that are shaped like the letter “J” where the conduit leading to the outlet of each of the U-tubes is significantly longer than the conduit extending form the inlet. Accordingly, the actives surface of the heat-exchanging device 60g has two levels, 17b where the inlets of the U-tubes are located and 17a where the outlets of the U-tubes are located. Both 17a and 17b are parallel and oppose the HT-surface 19, similar to FIG. 6f. Moreover, this structure creates elongated cavities 63 (i.e. long cavities in the direction perpendicular to the plane of the drawing), thus block 13 is an integral structure that includes fine delivery channels (meaning cavities 63), yet a cover that may include fine evacuation channels has to be added. Another option is to join two outlet conduits than each two outlets 65a at 17a will be merged to one (65b) thus reducing the pressure losses. FIG. 6h illustrates, in accordance with another preferred embodiment of the present invention, a cross sectional view of a heat-exchanging device 60h, built of two jointed blocks 13 & 15. This cross sectional view includes a row of a plurality of U-tubes 14b that are shaped like the letter “V” where the actives surface 17 of the heat-exchanging device 60g is staggered, presenting a non-continuous plane.

FIG. 6g illustrates, in accordance with another preferred embodiment of the present invention, a cross sectional view of a heat-exchanging device 60g, built of two jointed blocks 13 & 15. This cross sectional view includes a row of a plurality of J-like cooling tubes 14a where the outlet conduit of each of the U-tubes is longer than the inlet conduit of each of the U-tubes.

FIG. 7a illustrates, in accordance with a preferred embodiment of the present invention, a top view of a heat-exchanging device 70, i.e. the active-surface 17 of 70. In this embodiment two close U-tubes are arranged in opposing rows thus each U-tube inlet 16 belongs to a row of two inlets and each U-tube outlet 18 belongs to a row of two inlets. Accordingly the number of fine channels may be reduced by a factor of 2, as shown in FIG. 7b. FIG. 7b illustrates, in accordance with a preferred embodiment of the present invention, delivery and evacuation channeling, with respect to the U-tubes arrangement of FIG. 7a, where the fine delivery channels 42 supply the fresh coolant to the heat-exchanger device 72 and each of channels is fluidically connected to half of the row of two U-tubes inlets, as it this arrangement there are two main delivery manifolds 44 on opposing sides of 72. In this arrangement, the pressure drop may be significantly reduced due to (1) an increase in the cross section area of 42, when it delivers coolant to two rows of U-tubes (see FIG. 7a), and (2) by reducing to half the mass flow rate through 42, when applying two main delivery manifold 42. The outlets rows of 72 may be fluidically connected to the fine evacuation channels 46 and each of 46 may be fluidically connected to the main evacuation manifold 48.

FIG. 8a illustrates, in accordance with another preferred embodiment of the present invention, a top view of a heat-exchanging device 80, i.e. the active-surface 17 of 80. In this embodiment the U-tubes are arranged in four quarters, where in each of the quarters the arrangement of U-tubes is similar to the arrangement shown in FIG. 7a. Such an arrangement provides the option to apply the fine delivery channels 42 from all sides as shown in FIG. 8b.

FIGS. 9a-9c illustrate, in accordance with preferred embodiments of the present invention, several packaging approaches. FIG. 9a shows a rectangular basic cell arrangement 92 where the overall area of both the inlet 16 and the outlet 18 of the U-tubes 14 occupies less than half of the active surface 17 as applied in the heat-exchanging device 93. FIG. 9b shows a rectangular basic cell arrangement 94 where the overall area of both the inlet 16 and the outlet 18 of the U-tubes 14 occupies more than half of the active surface 17 as applied in the heat-exchanging device 95. In such a rectangular arrangement, the overall area of the U-tubes inlets and outlets is limited to about 66% of the active surface 17 of 95. However, FIG. 9c shows a staggered (or hexagonal) basic cell arrangement 96 where the area of both the inlet 16 and the outlet 18 of the U-tubes 14 occupies much more than half of the active surface 17 as applied in the heat-exchanging device 97. In such a staggered arrangement, the overall area of the U-tubes inlets and outlets may be increased to about 80% of the active surface 17 of 97.

FIG. 10a illustrate, a typical case where the top surface heat flux of an heat-generating element 100 (for example, a CPU) is not uniform, and in particular hot-spots exist at restricted areas 102 where the heat flux are significantly intensive with respect to the average heat flux of 100. Accordingly, a non-uniform heat-exchanger device may be designed as shown in FIG. 10b. FIG. 10b illustrates in accordance with a preferred embodiment of the present invention a heat-exchanging device 104 with a special U-tubes arrangements. In most of the active area 17 (i.e. areas 108) of 104, low-density arrangement of U-tubes is applied, but at restricted areas 106 of 17 high-density arrangement of U-tubes is applied in order to provide local high heat-removal performance in accordance to the hot-spots of the heat-generating element 100 shown in FIG. 10a.

The heat-exchanger device of the present invention may be operated at different operational conditions and provide increasing performance in terms of heat-removal per unit of area with respect to the operational pressure. The heat-exchanger device is an ideal heat-exchanger with respect to the heat-capacity of the coolant liquid but from practical system considerations, without derogating generality, an optimized heat-exchanger device may reach a cooling efficiency that is in the range of 75-100% of the ideal cooling potential. FIG. 11 shows simulated prototype results of the performance of an optimized heat-exchanger device with respect to the pressure supply for air-cooling at temperature gap of 30° K. (i.e. the temperature gap between the heat-generating element and the colder air). Due to early optimization considerations (minimizing pressure losses through the U-tubes), the results were obtained for the case where the overall area of the inlets and the outlets of the U-tubes occupies 70% of the active area of the heat-exchanger device. It is clearly seen that the greater the pressure supply, the significantly lower the heat transfer per unit of area is. Practically speaking, air supply of up to few millibars (1 millibar=100 Pascal) is typical for desktop CPUs cooling (fans and small blowers) where teat transfer rates of up to 10 watts/cm² meet the cooling requirements, and air supply of up to few tens of millibars is typical for desktop main-frames and servers (i.e. system with large number of CPUs) cooling (including blade servers and communication oriented servers where the task of cooling are not only dedicated to CPU cooling). However, the potential of extremely large heat-removal per unit of area cooling performance at higher air pressure supply is clearly seen from FIG. 11, in particular at compressible flow (above 300 mbar) where heat-transfer enhancement exists due to compressible effects of fluid flow expansion. It has to be emphasized that pre-cooling of the coolant may enhance the heat removal performances. In addition, it has to be emphasized that the coolant may be any practical liquid and not only air, for example, heat transfer rate of 3000 watts/cm² and more may be provided when using high pressure water as the coolant used in the heat-exchanger device of the present invention.

The simulated results (as shown in FIG. 11) provide also various indications that may be used in the design of an optimized heat exchanger device. FIG. 12 presents a table of optimized data for increasing pressure supply of coolant (air). It has to be emphasized that the data presented at this table is of typical values that may used as guide-lines for a design but for many practical applications, with respect to system and compactness considerations, changing the optimized geometrical parameters (such as D—diameter—and L—length—, see FIG. 12a) even by a factor of 2 or more may provide a well functioning heat-exchanger device. The simulated results clearly indicate that:

As the pressure increases, the Inlets/outlets diameter D of the U-tubes must be reduced for optimal heat-exchanger design.

As the pressure increases, the length L of the inlets/outlets conduits of the U-tubes must be increased for optimal heat-exchanger design (for a U-shaped tube, L is the height of the tube, i.e. about a half of the length of the entire tube, neglecting the bottom lateral portion).

Accordingly the ratio L/D must rapidly increase as the pressure (of the supplied fluidic coolant) increases.

As D decreased, greater number of U-tubes per unit of area (see coulomb “N” in the table) must be provided to obtain optimal heat-exchanger design.

Similar to the performance graph shown in FIG. 11, the heat transfer rates (HT) are significantly increased as the pressure increases.

The optimization suggests that as the pressure increased and D decreases, the efficiency of the heat removal (HTeff) with respect to the full potential of cooling (i.e. ideal cooling where the coolant temperature at the U-tubes exit is equal to the temperature of the heat-generating element), may reduce by 2-23% from ideal values. It is due to the fact that when trying to increase that efficiency, the mass flow rate is reduced as pressure losses are increased and the overall effect is reducing of heat-removal performance (at a given pressure supply).

Note that by the word “diameter” relates, in the context of the present specification, to any shape of the inlet and the outlet, and specifically with respect to FIG. 12, it relates to the diameter on the surface (even if it is different further downstream).

FIG. 13 illustrates, with respect to a preferred embodiment of the heat-exchanging system of present invention a typical cooling system for providing heat removal to main-frames or servers (including blade-servers or server that used for communication duties). In such as server a plurality of CPU are assembled in one system, and it may involve additional cooling needs such as other heat generating elements, for example video cards, graphic chips (or graphic engines), as well as broad-bend communication cards, and central power-supply unit. FIG. 13 illustrates a blade-server architecture, where a plurality of motherboards (being the “blades”) each equipped with one or several CPUs and optionally other heat-dissipating elements. The motherboards are vertically assembled substantially in parallel within one enclosure (or drawer). Typically a blade-server system may include several enclosures rack mounted one above the other in one frame. For simplicity, the cooling system 200 includes several blades 210 of only one enclosure, each of it includes one CPU having an integral heat-exchanger according to the present invention on top of it, 201 (notice that more than one CPU and additional heat-generating elements may be incorporated in one blade). Each of the heat-exchangers has a main delivery channel 203 for fresh air supply and a main evacuation channel 202. The plurality of main delivery channels 203 coming from each of the blades 210 are fluidically connected through a central delivery pipeline 213 to an air-supply unit 230, for example one or more air blowers. As already mentioned suction device such as vacuum pump may be used to drive the coolant, (alternatively or additionally). Optional air-treatment unit 280 may also be provided. 280 may include pre-cooling system, like filters and drying system. The blower mass-flow-rate is compatible with the overall cooling needs. The air-treatment unit 280 may be used for precooling the supplied air (or any other coolant), and filter it from contaminants. In addition, the blower may be mounted at an external area or may be acoustically shielded in order to reduce the noise level at the server area. The plurality of main evacuation channels 202 coming from each of the blades 210 is fluidically connected to a central evacuation pipeline 212. It is an option to cross the room walls 214 and place the exit 215 of 212 outside in order to exhaust the hot air into the external atmosphere. The main pipe-lines 212 and 213 may thermally be insulated using common thermal isolation shields and materials. Secondary pipe-lines 214 for cooling the central power-supply 250 may also be included. In addition, a central thermal management or control unit 260 may be provided, having input several temperature sensors and I/O signals, i.e. communication with the air-supply units 230 and 280. It may also be connected to the CPUs for integral thermal management inside the CPU itself. The thermal management of the blade-server may incorporate fans 270 for dissipating the remaining heat generated by low-power elements, or supply external cooling air through outlets 275, which may be connected to air supply 230 or to other independent air-supply means.

A second type of heat-sink with respect to another preferred embodiment of the present invention is shown in FIGS. 14a-e. Similar to the heat-exchanger device that is based on U-tubes, the overall area of the internal cooling tubes may inflationary be increased when reducing the scales and adding more cooling tubes, and similarly, the rule of scaling down is a Fractal-like rule where the overall volume of the tubes is kept constant. However, the heat exchanger device that is bases on U-tubes is of different topology from the exchanger device described in FIGS. 14a-e in the following manner; While the inlets and the outlets of the U-tubes are positioned on the active surface of the heat-exchanger device and the active surface of the heat-exchanger device is substantially opposite to the HT-surface of the heat-exchanger device, the inlets and the outlets of the cooling tubes of the exchanger device described in FIGS. 14a-e are placed at substantially opposing surfaces and these two surfaces are substantially perpendicular to the HT-surface of the heat-exchanger device described in FIGS. 14a-e.

FIG. 14a illustrates a top view of a heat-exchanger device 140 in accordance with yet another preferred embodiment of the present invention, based on straight cooling tubes to be referred hereafter as I-tubes. Device 140 has short perforated cooling fins 141 mounted on the base 152 of device 140 where in between them an integral fine-delivery channels 144 and fine evacuation channels 146 are created. Manifolds 144 are fluidically connected to the main delivery manifold 142 and manifolds 146 are fluidically connected to the main evacuation manifold 148. The cooling fins 141 are perpendicular to the base 152 and the HT-surface 149 (see FIG. 14b) of the heat-exchanger device 140 and each of the fins 141 includes a large number of cooling tubes 154, i.e. I-tubes passing through the fin. FIG. 14b illustrates a cross sectional view of one cooling fin 141 (see cross section A-A). The heat flux (Q) from the heat-generating element comes from the HT-surface 149 of the fin base 152. The cooling fins 141 comprise a plurality of I-tubes 154. The basic cell 155 of this I-tubes arrangement contains one I-tubes 154 and is made of a heat-conducting material. Without derogating generality, for anticipated CPU cooling tasks typical height (H) of the cooling fins 141 is 4-20 millimeter and the length (L) of I-tubes 154 is a few millimeters. FIG. 14c clarifies the rule of down scaling of the I-tubes 154 of device 140, where arrangement 151a is created by using 3 down scaled basic cells 155 by factor of 2, and the fine arrangement 151b is created by using 4 down scaled basic cells 155 by factor of 2 (arrangements 151a and 151b have same area). This scaling down principle is similar to the scaling down principle outlined hereinabove with respect to FIGS. 3a-d, thus the heat-exchanger device 140 with the perforated fines is similar in most details, in particular with respect to the heat-exchange process, to the heat-exchanger device that was described in FIG. 1 and in more details in FIG. 3 through FIG. 13.

The heat exchanging process (see FIG. 14a) is taking place when the fresh air coming from manifolds 144 penetrates through the I-tubes 154 at a “slalom” course to the manifolds 146, as illustrates by the fine curved arrows. Illustrative three-dimensional view of a portion of the heat-exchanger device is given in FIG. 14d where the base plate 152 with the HT-surface 149 and the cooling fins 141 mounted on the top of surface of 152. In this view, it is clearly seen than the fine delivery channels 144 and fine evacuation channels 146 are created between the cooling fins 141. FIG. 14e illustrates the heat exchanger device 140 mounted over a heat-generating device such as a CPU (162). The CPU 162 is mounted on board 164. A heat-spreader 166 is optionally provided between 140 and 162, where the HT-surface 149 is the contact surface. This cross-sectional illustration shows the cooling fins 141 and the manifolds 144 and 146, where manifolds 144 and 146 are confined and closed as a top cover 168 is provided.

The heat-exchanger device of the present invention may exchange heat with a solid objects, but also with gases or liquids.

The cooling or heating fluid may be supplied from a low-pressure source (typically of less than 2 mbar), a moderate pressure source (typically of less than 200 mbar) or a high-pressure source (typically more than 200 mbar and also more than 5 bars). Both gases and liquid may be used as coolants and as much as the thermal capacity of the coolant is larger, the potential of cooling is larger

Generally speaking, the greater the supply pressure, the greater the potential of cooling or heat exchanging. The greater the density of the coolant, the greater the potential of cooling.

Generally speaking, as much as the mass-flow rate of the coolant is larger, the potential of cooling is larger. The cooler the coolant is with respect to the temperature of the heat-generating element (ΔT), the greater the potential of cooling.

Generally speaking, the greater the overall surface of the heat-exchanger internal cooling tubes, the greater the potential of cooling. Generally speaking, the greater the thermal-conductivity of the heat-exchanger structural material is, the greater the potential of cooling. Examples of good heat-conducting materials are Aluminum or Copper, as well as non-metallic materials having high thermal conductivity.

It has to be emphasized that several of the parameters mentioned herein are dependent parameters.

The object to be cooled may be flat or curved, and correspondingly, the shape of the heat exchanger's facing surface (the HT-surface) would be of the same shape, so as to fit it properly and allow heat-flux without thermal resistance. In some preferred embodiments of the present invention, the heat-exchanger can be of a uniform width. In other embodiments it may have a non-uniform width.

The heat exchanger of the present invention may be designed as a compact unit having same dimensions as the heat-generating element, or much different dimensions: either larger or smaller than the heat-generating element (naturally, a larger heat-exchanger is preferable).

In a preferred embodiment of the present invention the heat-exchanger device may be designed as a thin rectangular unit having relatively small width with respect to its lateral dimensions. This appears to be suitable for compact cooling conventional electronic chips.

It should be clear that the description of the embodiments and attached Figures set forth in this specification serves only for a better understanding of the invention, without limiting its scope.

It should also be clear that a person skilled in the art, after reading the present specification could make adjustments or amendments to the attached Figures and above described embodiments that would still be covered by the present invention.

1. A heat-exchanging device comprising:
a block made from a heat-conducting material with a plurality of cooling tubes provided in it, each of the cooling tubes having an inlet for receiving an inflow of a coolant fluid and an outlet for evacuating the coolant fluid, the inlet and the outlet of each cooling tubes are distributed on at least one active surface, which is substantially opposite a heat-transfer surface of the heat-exchanging device, wherein each cooling tube is designed to direct the coolant fluid towards and then away from said at least one heat-transfer surface,
whereby when subjected to a heat flux through the heat-transfer surface and when coolant fluid passes through the cooling tubes it absorbs heat from the block and evacuates it away.

2. The device of claim 1, wherein the heat-conducting material is selected from the group of materials containing Aluminum and Copper.

3. The device of claim 1, provided with a heat-spreader coupled to the heat-transfer surface of the heat-exchanging device.

4. The device of claim 1, wherein the active surface is flat.

5. The device of claim 1, wherein the active surface is staggered.

6. The device of claim 1, wherein the active surface has levels of different elevations.

7. The device of claim 1, wherein the heat-transfer surface is flat.

8. The device of claim 1, wherein the cooling tubes are each U-shaped.

9. The device of claim 1, wherein the cooling tubes are each J-shaped.

10. The device of claim 1, wherein the cooling tubes are each V-shaped.

11. The device of claim 1, wherein the cooling tubes each have a diameter that is not greater than 1 mm.

12. The device of claim 1, wherein the cooling tubes each have a diameter that is not greater than 0.7 mm.

13. The device of claim 1, wherein the cooling tubes each have a height that is not greater than 10 mm.

14. The device of claim 1, wherein the cooling tubes each have a height that is not greater than 6 mm.

15. The device of claim 1, wherein the inlets and outlets of the cooling tubes are distributed on the active surface at a density of between 50 to 1000 pairs of inlets and outlets per cm square.

16. The device of claim 1, wherein the inlets and outlets cooling tubes are distributed on the active surface at a rate of between 100 to 600 pairs of inlets and outlets per cm square.

17. The device of claim 1, wherein the total area taken by the inlets and outlets of the cooling tubes amounts between 50 to 85 percent of the total area of the active surface.

18. The device of claim 1, wherein the fluidic coolant is gas.

19. The device of claim 1, wherein the fluidic coolant is air.

20. The device of claim 1, wherein the fluidic coolant is liquid.

21. The device of claim 1, wherein the fluidic coolant is water.

22. The device of claim 1, wherein the fluidic coolant is a mixture of fluids.

23. The device of claim 1, wherein the fluidic coolant is a two-phase fluid.

24. The device of claim 1, wherein the block is made from two parts, a first part comprising a plurality of ducts passing through the part and a second part comprising a plurality of basins, whereby the parts are joined thus fluidically connecting couples of ducts via a basin to define the cooling tubes.

25. The device of claim 1, wherein the block is made from a plurality of substantially parallel plates in which sections of the cooling tubes are carved out.

26. The device of claim 25, wherein sections of a delivery manifold are also carved out in the substantially parallel plates.

27. The device of claim 26, wherein sections of an evacuation manifold are also carved out in the substantially parallel plates.

28. The device of claim 1, wherein inlets and outlets of the cooling tubes are arranged in respective rows.

29. The device of claim 28, wherein inlets and outlets of the cooling tubes are arranged in adjacent twin-rows.

30. The device of claim 28, wherein inlets and outlets are arranged in a staggered formation.

31. The device of claim 28, wherein the rows are arranged in zones of varying row orientations.

32. The device of claim 1, further comprising an evacuation manifold communicating with the outlets for evacuating the fluidic coolant.

33. The device of claim 32, wherein the evacuation manifold further comprises fine channels, each channel communicating with at least a portion of one row of outlets.

34. The device of claim 33, wherein the fine channels cross sectional area is larger at the entrance to the channels and smaller at the end of the channels.

35. The device of claim 1, further comprising a delivery manifold communicating with the inlets for delivering the fluidic coolant.

36. The device of claim 35, wherein the delivery manifold further comprises fine channels, each channel communicating with at least a portion of one row of inlets.

37. The device of claim 36, wherein the fine channels cross sectional area is larger at the entrance to the channels and smaller at the end of the channels.

38. The device of claim 36, wherein each of the fine channels of the delivery manifold communicating with at least a portion of two adjacent rows of inlets.

39. The device of claim 36, wherein each of the fine channels of the evacuation manifold communicating with at least a portion of two adjacent rows of outlets.

40. The device of claim 36, wherein the delivery manifold is integrated at least partly above the active surface.

41. The device of claim 36, wherein the fine channels of the delivery manifold are integral channels provided at the active surface and penetrate the block.

42. The device of claim 41, wherein the delivery manifold and the evacuation manifold are integrated to the active surface of the block one above the other.

43. The device of claim 36, wherein the delivery manifold and the evacuation manifold are integrated in one layer at least partly above the active surface of the block.

44. The device of claim 36, wherein the fine channels of at least of the delivery manifold or the evacuation channels are integral channels provided at the active surface and penetrate to the block.

45. The device of claim 36, wherein the delivery manifold is designed to introduce the fluidic coolant from a first direction and the evacuation manifold is designed to evacuate the fluidic coolant from a second direction.

46. The device of claim 45, wherein the second direction is substantially opposite to the first direction.

47. The device of claim 36, wherein the delivery manifold is designed to introduce the fluidic coolant from two or more directions relative to the device.

48. The device of claim 1, wherein the inlets and outlets are distributed on the active surface at a varying density.

49. The device of claim 1, wherein the cross-section of the cooling tubes is substantially round.

50. The device of claim 1, wherein the cross-section of the cooling tubes is substantially rectangular.

51. The device of claim 1, wherein the cooling tubes have varying cross-sectional area.

52. A heat-exchanging device for exchanging heat with a fluidic medium comprising:
a plate with a plurality of cooling tubes made from a heat-conducting material and extending from the plate, the cooling tubes aimed at being submerged in the fluidic medium, each of the cooling tubes having an inlet for receiving an inflow of a coolant fluid and an outlet for evacuating the coolant fluid, the inlet and the outlet of each cooling tubes are distributed on at least one active surface on the plate, wherein each cooling tube is designed to direct the coolant fluid towards and then away from the fluidic medium,
whereby when subjected to a heat flux through the heat-transfer surface and when coolant fluid passes through the cooling tubes it absorbs heat from the fluidic medium and evacuates it away.

53. A cooling system for cooling a plurality of heat-dissipating electronic devices of an electronic system, the cooling system comprising:
a plurality of heat-exchangers, each heat-exchanger designed to be coupled to one heat-dissipating electronic device and comprising at least one block made from a heat-conducting material with a plurality of cooling tubes provided in it, each of the cooling tubes having an inlet for receiving an inflow of a coolant fluid and an outlet for evacuating the coolant fluid, the inlet and the outlet of each cooling tubes are distributed on at least one active surface, which is substantially opposite a heat-transfer surface of the heat-exchanging device, wherein each cooling tube is designed to direct the coolant fluid in the general direction of said at least one heat-transfer surface and then divert it away from said at least one heat-transfer surface, and
fluidic coolant supply, for supplying fluidic coolant via piping to the plurality of heat-exchangers,
whereby when subjected to a heat flux through the heat-transfer surface and when coolant fluid passes through the cooling tubes of each heat-exchanger it absorbs heat and evacuates it away.

54. The system of claim 53, wherein the fluidic coolant is air.

55. The system of claim 53, wherein the fluidic coolant supply comprises an air blower.

56. The system of claim 53, wherein the fluidic coolant supply comprises a pressure pump.

57. The system of claim 53, the fluidic coolant supply comprises a vacuum pump.

58. The system of claim 53, wherein the fluidic coolant supply comprises a compressor.

59. The system of claim 58, wherein the blower is also used for ambient cooling of the electronic system interior.

60. The system of claim 53, further comprising a fan for ambient cooling of the electronic system interior.

61. The system of claim 53, further provided with pre-cooling means for pre-cooling the coolant fluid prior to passing it through the heat-exchangers.

62. The system of claim 53, further provided with evacuation means for evacuating hot fluidic coolant from the heat-exchangers.

63. The system of claim 62, wherein the evacuation means evacuates the hot fluidic coolant via piping to an external environment.

64. The system of claim 53, wherein the delivery pipe lines are insulated.

65. The system of claim 62, wherein the evacuation pipe lines are insulated.

66. The system of claim 53, wherein the electronic system comprises a plurality of electronic boards on which a plurality of heat-dissipating devices are mounted.

67. The system of claim 66, wherein at least one of the heat-exchangers cools an off-board element.

68. The system of claim 53, further provided with a central thermal control for thermal management of the electronic system.

69. A heat-exchanging device comprising:
a plurality of substantially parallel cooling fins provided between a first heat-spreader plate made from a heat-conductive material and a second substantially opposite cover plate, thus defining flow channels between the fins, each fin made from a heat conductive material and provided with a plurality of conduits passing through the fin, wherein the flow channels intermittently serve as supply and evacuation channels for a fluidic coolant, so that the coolant may pass through the conduits of fins,
whereby when subjected to a heat flux through the heat-transfer surface and when coolant fluid passes through the conduits it absorbs heat and evacuates it away.

70. The device of claim 69, wherein the supply channels are connected to a supply manifold.

71. The device of claim 69, wherein the evacuation channels are connected to an evacuation manifold.

72. The device of claim 69, wherein the cover plate is perforated to allow evacuation of hot fluidic coolant.
